(19) United States
(12) Patent Application Publication
(10) Pub. No.: US 2008/0032523 A1
(43) Pub. Date: Feb. 7, 2008

(54) CIRCUIT MODULE AND MANUFACTURING PROCESS THEREOF

(75) Inventor: Ching-Chi Kuo, Taoyuan Hsien (TW)

Correspondence Address: MADSON & AUSTIN, 15 WEST SOUTH TEMPLE, SUITE 900, SALT LAKE CITY, UT, 84101, US

(73) Assignee: Delta Electronics, Inc., Taoyuan Hsien (TW)

(21) Appl. No.: 11/563,281

(22) Filed: Nov. 27, 2006

(30) Foreign Application Priority Data
Aug. 1, 2006 (TW) 095128206

(51) Int. Cl. H05K 1/00

(52) U.S. Cl. 439/75

(57) ABSTRACT

A circuit module to be mounted on a system circuit board having first contact portions is provided. The circuit module includes a printed wire board and at least an electronic component mounted on the printed wire board. The printed wire board includes a substrate and a trace pattern formed on at least a surface of the substrate. At least an edge side of the substrate has second contact portions corresponding to the first contact portions of the system circuit board and in contact with the trace pattern.

### FIELD OF THE INVENTION

The present invention relates to a circuit module, and more particularly to a circuit module to be mounted on a system circuit board. The present invention also relates to a process of manufacturing such a circuit module.

### BACKGROUND OF THE INVENTION

With increasing development of electronic industries, the internal circuitries of an electronic device are advanced toward modulization. In other words, plural electronic components are mounted on a printed wire board (PWB) and thus many functions are integrated into a single circuit module. For example, a power module is a common circuit module. An example of the power module includes a DC-to-DC converter, an AC-to-DC converter, and the like. For manufacturing the power module, the electronic components such as capacitors, resistors, inductors, transformers, diodes and transistors are mounted on a printed wire board by a surface mount technology (SMT). Nowadays, power modules have experienced great growth and are rapidly gaining in popularity because the layout configurations thereof are flexible and the heat-dissipating efficiencies are enhanced.

In addition, a connector is usually mounted on an edge of the power module by a surface mount technology (SMT). Via the edge connector, the power module is connected to a system circuit board. Referring to FIGS. 1(a), 1(b) and 1(c), three power modules 1 having different edge connectors 13, 14 and 15 are schematically illustrated. In FIG. 1(a), an electronic component 11, a heat sink 12 and a first-type edge connector 13 are mounted on the printed wire board 10 by a surface mount technology (SMT). In FIG. 1(b), an electronic component 11, a heat sink 12 and a second-type edge connector 14 are mounted on the printed wire board 10 by a surface mount technology (SMT). In FIG. 1(c), an electronic component 11, a heat sink 12 and a third-type edge connector 15 are mounted on the printed wire board 10 by a surface mount technology (SMT). The electronic component 11 indicates at least a capacitor, at least a resistor, at least an inductor, at least a transformer, at least a diode, at least a transistor and the like. For clarification, only one electronic component is shown in the drawings.

As shown in FIG. 1(a), the edge connector 13 is produced by an injection-molding process such that plural pins 131 are fixed on a plastic frame 130. These pins 131 are referred as surface mount device (SMD) pins. The tip portions 1310 of the SMD pins 131 are bent to be perpendicular to the surface of the printed wire board 10. This edge connector 13 is also referred as a SMD type connector. Generally, the process of mounting the edge connector 13 on a system circuit board (not shown) via the surface mount technology (SMT) principally comprises the following steps. Firstly, a solder paste is coated onto the contact pads of the system circuit board, and then the tip portions 1310 of the SMD pins 131 are precisely placed on the contact pads by using automatic placement equipment. Then, this SMD type connector and the system circuit board are heated in a reflow furnace to melt the solder paste. Afterward, the system circuit board is then cooled to solidify the solder paste so as to bond the tip portions 1310 of the SMD pins 131 onto the system circuit board. Since the SMD pins 131 are thin and crowded, the amount of the solder paste is limited and thus the adhesion between this SMD type connector and the system circuit board is insufficient. In other words, the SMD type connector is readily detached from the system circuit board when suffered from a drop or a strong impact. Moreover, since each of the SMD pins 131 is very long and bent twice, the power loss is high if a current passes therethrough.

As shown in FIG. 1(b), the edge connector 14 is produced by an injection-molding process such that plural SMD pins 141 and plural support pins 142 are fixed on a plastic frame 140. The tip portions 1410 of the SMD pins 141 are bent to be perpendicular to the surface of the printed wire board 10. The tip portions 1410 of the SMD pins 141 are bent to be perpendicular to the surface of the printed wire board 10. The support pins 142 are parallel to the surface of the printed wire board 10. For mounting the edge connector 14 on a system circuit board (not shown) via the surface mount technology (SMT), a solder paste is firstly coated onto the contact pads of the system circuit board, and then the tip portions 1410 of the SMD pins 141 are precisely placed on the contact pads by using automatic placement equipment. After the reflowing and cooling steps as described above, the tip portions 1410 of the SMD pins 141 are fixed onto the system circuit board. The support pins 142 are inserted into corresponding retaining holes in the system circuit board to assist the edge connector 14 to be firmly fixed on the system circuit board. In comparison with the edge connector 13, this edge connector 14 can withstand a stronger impact. Unfortunately, since each of the SMD pins 141 is still long and bent twice, the power loss is high.

As shown in FIG. 1(c), the edge connector 15 is produced by an injection-molding process such that plural SIP (single in-line package) pins 151 are fixed on a plastic frame 150. These SIP pins 151 are parallel to the surface of the printed wire board 10. This edge connector 15 is also referred as a SIP type connector. For mounting the edge connector 15 on a system circuit board (not shown), the SIP pins 151 are inserted into corresponding conducting holes of the system circuit board, and then a solder paste is applied on the peripheries of the conducting holes and the SIP pins 151. After the reflowing and cooling steps as described above, the SIP pins 151 are fixed onto the system circuit board. Since each of the SIP pins 151 is still long, the power loss is high.

As previously described, these convention edge connectors 13, 14 and 15 may increase power loss because they have long current paths and long pins. In addition, the edge connectors 13, 14 and 15, which are produced by injection-molding processes, are costly and have huge overall volume.

### SUMMARY OF THE INVENTION

It is an object of the present invention to provide a circuit module and a manufacturing process, which is cost-effective and time-saving.

It is another object of the present invention to provide a circuit module and a manufacturing process in order to reduce power loss when the circuit board is mounted on a system circuit board.

In accordance with an aspect of the present invention, there is provided a circuit module to be mounted on a system circuit board having first contact portions. The circuit module comprises a printed wire board and at least an electronic component mounted on the printed wire board. The printed wire board includes a substrate and a trace pattern formed on at least a surface of the substrate. At least an edge side of the substrate has second contact portions corresponding to the first contact portions of the system circuit board and in contact with the trace pattern.

In accordance with another aspect of the present invention, there is provided a process of manufacturing a circuit module to be mounted on a system circuit board. The process comprises the steps of providing a substrate and forming a trace pattern on the substrate, thereby producing a printed wire board; forming second contact portions on at least an edge side of the printed wire board corresponding to the first contact portions of the system circuit board and the trace pattern of the printed wire board; and mounting electronic components on the printed wire board according to the trace pattern.

In accordance with another aspect of the present invention, there is provided a process of manufacturing a circuit module to be mounted on a system circuit board. The process comprises the steps of providing a substrate and forming a trace pattern on said substrate, thereby producing a printed wire board; forming second contact portions on at least an edge side of said printed wire board corresponding to said first contact portions of said system circuit board and said trace pattern of said printed wire board; mounting electronic components on said printed wire board according to said trace pattern; and welding said second contact portions of said printed wire board onto said first contact portions of said system circuit board.

The above contents of the present invention will become more readily apparent to those ordinarily skilled in the art after reviewing the following detailed description and accompanying drawings, in which:

### BRIEF DESCRIPTION OF THE DRAWINGS

FIGS. 1(a), 1(b) and 1(c) are schematic views illustrating three power modules having different edge connectors;

FIG. 2 is a schematic view of a circuit module according to a preferred embodiment of the present invention;

FIGS. 3(a)˜3(e) are schematic views illustrating a process of manufacturing the circuit module of the present invention and electrically connecting the circuit module with a system circuit board;

FIG. 4 is a schematic view of a circuit module according to another preferred embodiment of the present invention;

FIG. 5 is a schematic cross-sectional view illustrating a support pin used for assisting the power module to be firmly fixed on the system circuit board;

FIG. 6(a) is a partial schematic view of a circuit module according to another preferred embodiment of the present invention, in which the edge contact portions of the printed wire board are covered by corresponding conductive elements;

FIG. 6(b) is a schematic cross-sectional view of the printed wire board of FIG. 6(a) taken along the line B-B′;

FIG. 7 is a partial schematic view of a circuit module according to another preferred embodiment of the present invention, in which the printed wire board has edge contact portions and at least a support structure on a edge side thereof;

FIG. 8 is a schematic cross-sectional view illustrating the support structure used for assisting the power module to be firmly fixed on the system circuit board; and

FIGS. 9(a)˜9(e) are schematic views illustrating another process of manufacturing the circuit module of the present invention and electrically connecting the circuit module with a system circuit board.

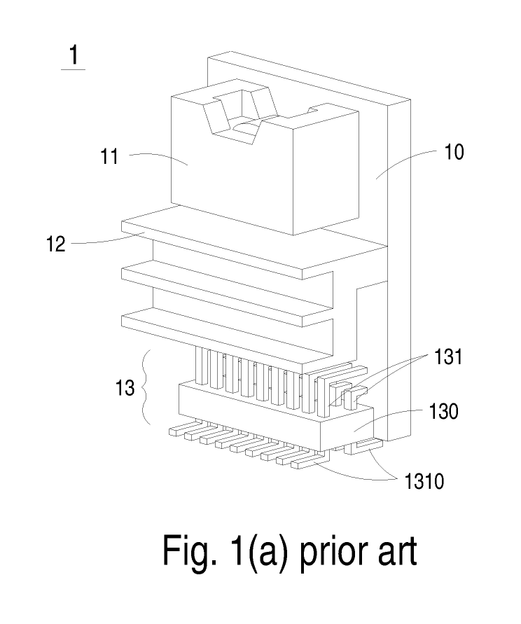

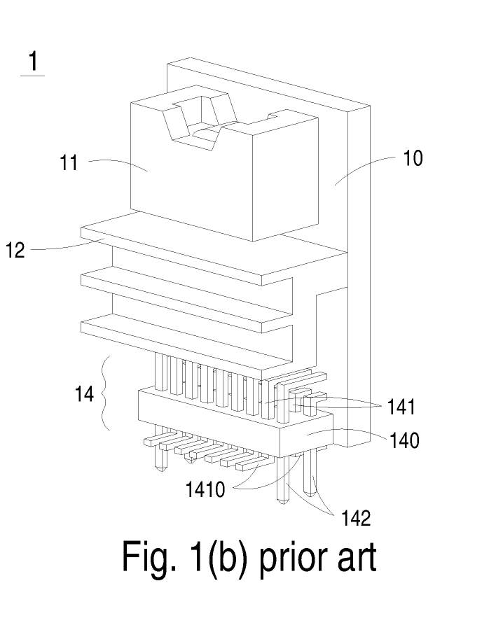

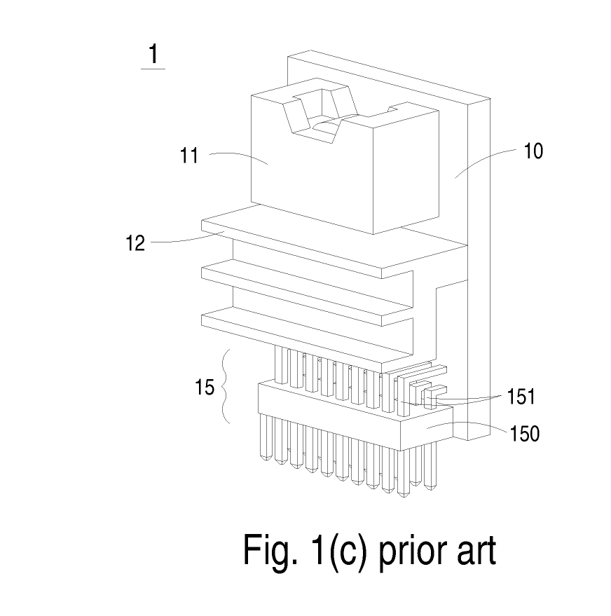

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

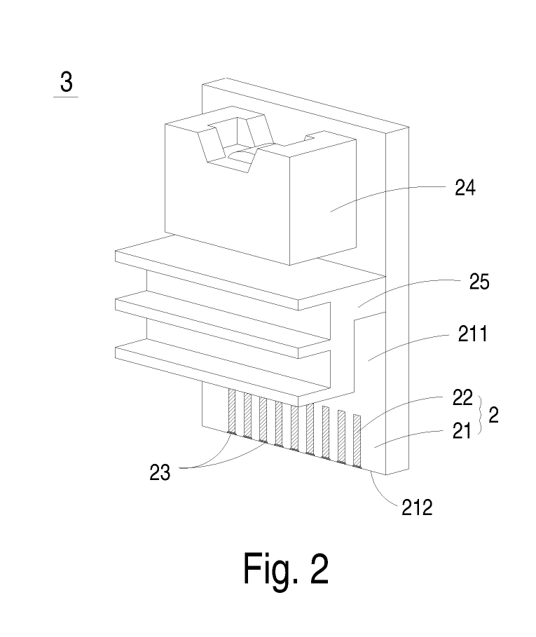

Referring to FIG. 2, a schematic view of a circuit module according to a preferred embodiment of the present invention is illustrated. In this embodiment, the circuit module 3 is a power module to be electrically connected with a system circuit board (not shown). The power module 3 comprises a printed wire board 2, an edge connecting portion 23 and at least an electronic component 24. The printed wire board 2 includes a substrate 21 and a trace pattern 22. The edge connecting portion 23 is formed on at least an edge side of the printed wire board 2. In some embodiments, the second contact portions 23 are formed at any edge side or different edge sides. The electronic component 24 is mounted on a surface 211 of the printed wire board 2. The edge connecting portion 23 is connected to the trace pattern 22, which is electrically connected to the electronic component 24. Via the edge connecting portion 23, the power module 3 will be mounted on the system circuit board by for example a surface mount technology (SMT), so that the power module 3 is electrically connected to the system circuit board. Optionally, at least a heat sink 25 is mounted on the surface 211 of the substrate 21 for dissipating heat generated from the power module 3.

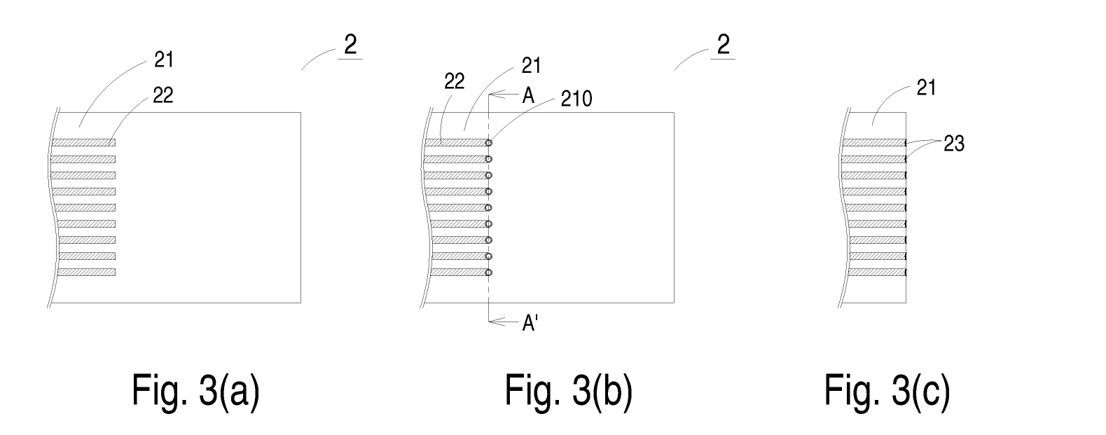

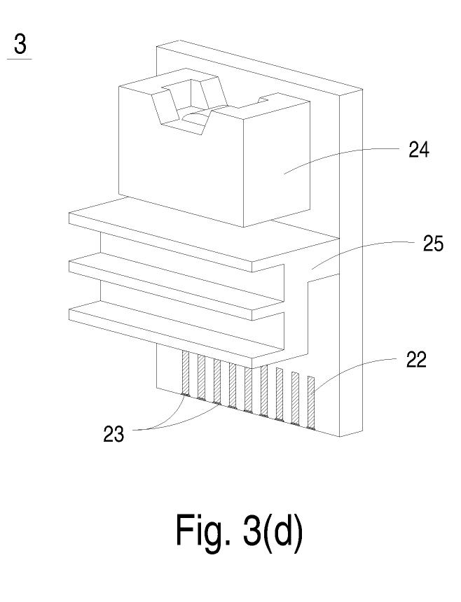

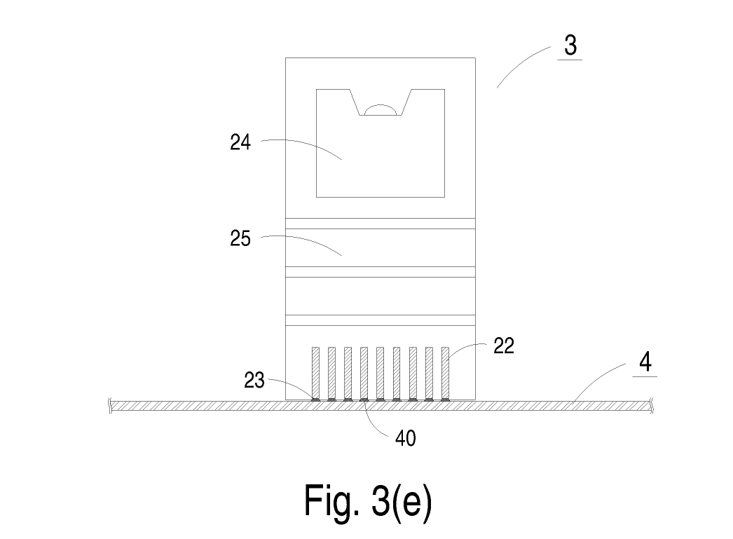

Hereinafter, a process of manufacturing the circuit module of the present invention and electrically connecting the circuit module with a system circuit board will be illustrated as follows with reference to FIGS. 3(a)˜3(e).

First of all, as shown in FIG. 3(a), a substrate 21 is provided. The substrate 21 is made of epoxy resin or other plastic material according to known process of fabricating printed wire boards. Then, a thin conductive layer such as a copper foil layer is formed on one or both surfaces of the substrate 21. After the undesired conductive layer is removed, the designed trace pattern 22 is printed on the substrate 21, thereby fabricating a printed wire board (PWB) 2.

Next, as shown in FIG. 3(b), according to a known plated-through-hole (PTH) technology, a plurality of through holes are drilled at the terminal portion of the trace pattern 22 or at the connecting portion between the terminal portion of the trace pattern 22 and a base line A-A′. As is also shown in FIG. 3(e), the locations of the through holes correspond to those of first contact portions 40 (e.g. contact pads) on a system circuit board 4. After the through holes are drilled, metallization are implemented on the sidewalls of the through holes 210 by an electroplating technology, thereby forming plated through-holes 210.

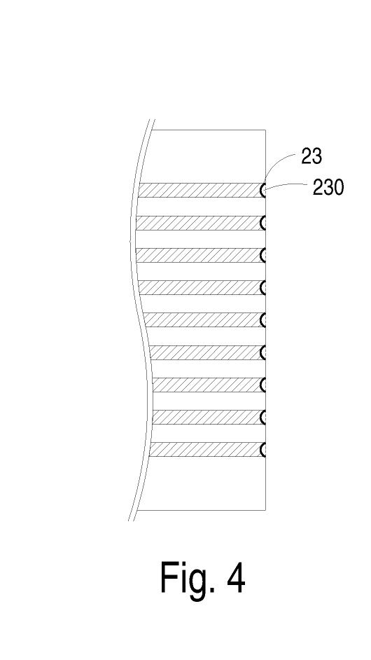

Then, the printed wire board 2 is cut into two parts along the locations of the plated through-holes 210, i.e. along the base line A-A′, so that a plurality of second contact portions 23 are formed on at least an edge side of the printed wire board 2, as shown in FIG. 3(c). In this embodiment, the surfaces of the second contact portions 23 are substantially flat with respect to the edge side of the printed wire board 2. Alternatively, there is a gap 230 between the second contact portions 23 and the edge side of the printed wire board 2, as is shown in FIG. 4.

Next, as shown in FIG. 3(d), an electronic component 24 and/or a heat sink 25 are mounted on the printed wire board 2 by for example a surface mount technology (SMT), thereby fabricating the power module 3. In this embodiment, the electronic component 24 indicates at least a capacitor, at least a resistor, at least an inductor, at least a transformer, at least a diode, at least a transistor and the like. For clarification, only one electronic component is shown in the drawings. An example of the transformer includes the conventional transformer, plate-to-plate sandwiched transformer, and the like.

Afterwards, as shown in FIG. 3(e), a solder paste is coated onto the first contact portions 40 of the system circuit board 4, and then the second contact portions 23 of the power module 3 are precisely placed on the first contact portions 40. By using a surface mount technology (SMT), the second contact portions 23 are welded onto the first contact portions 40, so that the power module 3 is mounted on the system circuit board 4.

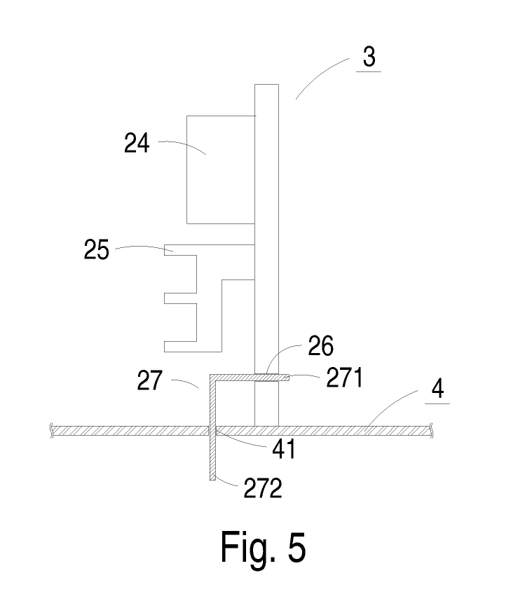

For assisting the power module 3 to be firmly fixed on the system circuit board 4, the printed wire board 2 further includes one or more first retaining holes 26 corresponding to the second retaining holes 41 formed in the system circuit board 4, as is shown in FIG. 5. During the process of mounting the electronic component 24 and/or the heat sink 25 on the printed wire board 2 as shown in FIG. 3(d), the first ends 271 of several support pins 27 are also mounted on the printed wire board 2. Sequentially, during the process of mounting the second contact portions 23 of the power module 3 on the system circuit board 4, the second ends 272 of the support pins are also mounted into the second retaining holes 41 of the system circuit board 4. As a consequence, the support pins 27 are effective for assisting the power module 3 to be firmly fixed on the system circuit board 4.

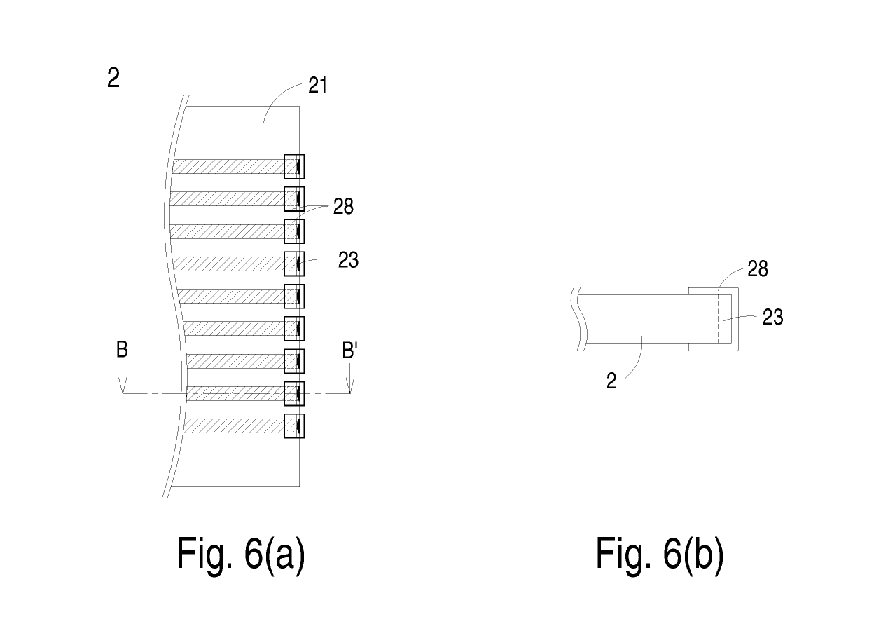

In some embodiments, for enhancing the adhesion and the contact area between the second contact portions 23 of the power module 3 and the first contact portions 40 of the system circuit board 4, the second contact portions 23 are covered by corresponding conductive elements 28. These conductive elements 28 are fabricated after the procedure of FIG. 3(c) or after or during the procedure of FIG. 3(d). Please refer to FIG. 6(b), which is a cross-sectional view illustrating the printed circuit board 2 of FIG. 6(a) along the line B-B′. The conductive elements 28 enclose and contact the second contact portions 23. Preferably, the conductive elements 28 are made of copper.

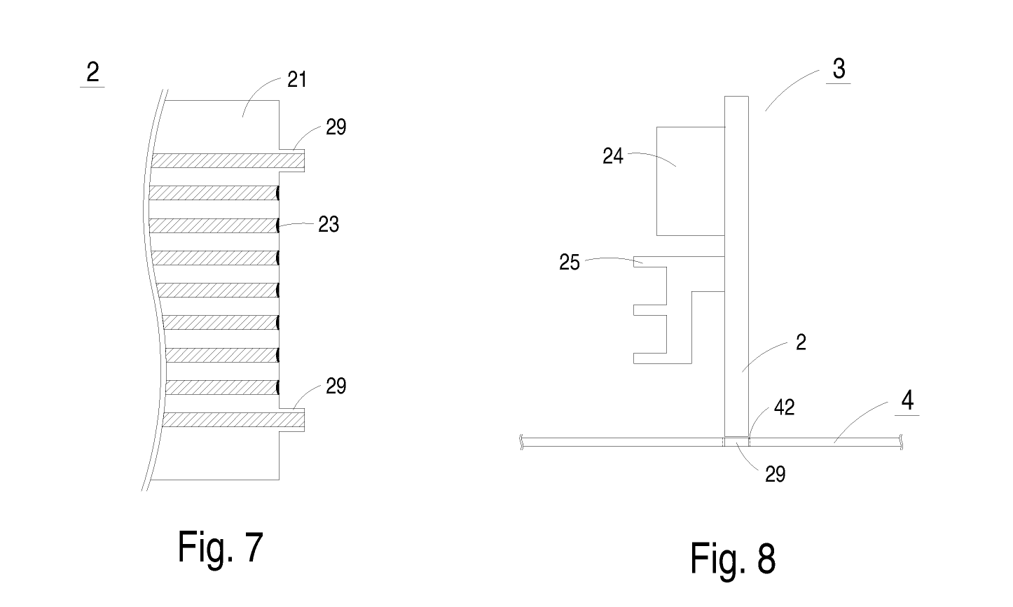

In some embodiments, the procedures of FIGS. 3(b) and 3(c) are modified to result in a support structure. For example, after a plurality of through holes are drilled by the PTH technology, the printed wire board 2 is cut into two parts along the locations of the plated through-holes 210 such that the second contact portions 23 and at least a support structure 29 are simultaneously fabricated, as is shown in FIG. 7. For assisting the power module 3 to be firmly fixed on the system circuit board 4, the system circuit board 4 has at least a third retaining hole 42 corresponding to the support structure 29. During the process of mounting the second contact portions 23 of the power module 3 on the system circuit board 4 by the surface mount technology (SMT), the support structure 29 is also mounted into the third retaining hole 42 of the system circuit board 4. As a consequence, the support structure 29 is effective for assisting the power module 3 to be firmly fixed on the system circuit board 4.

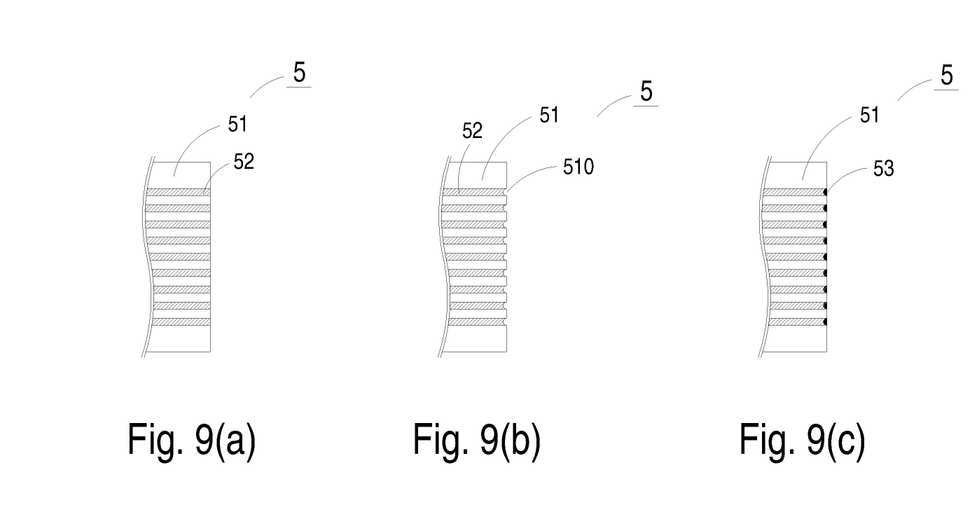

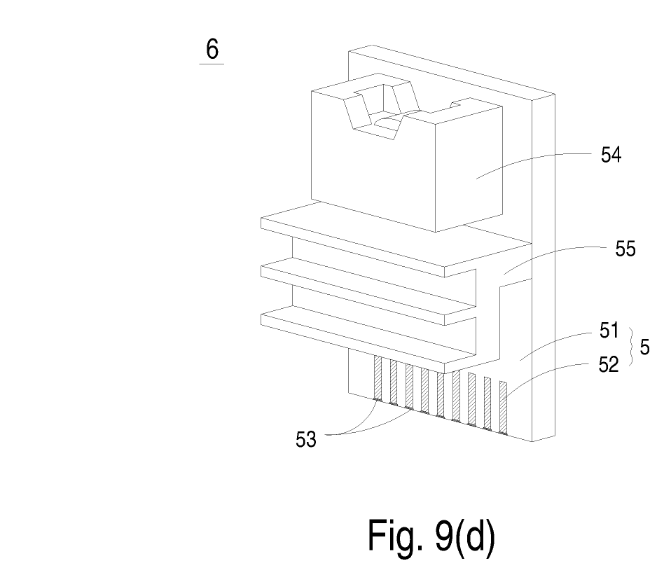

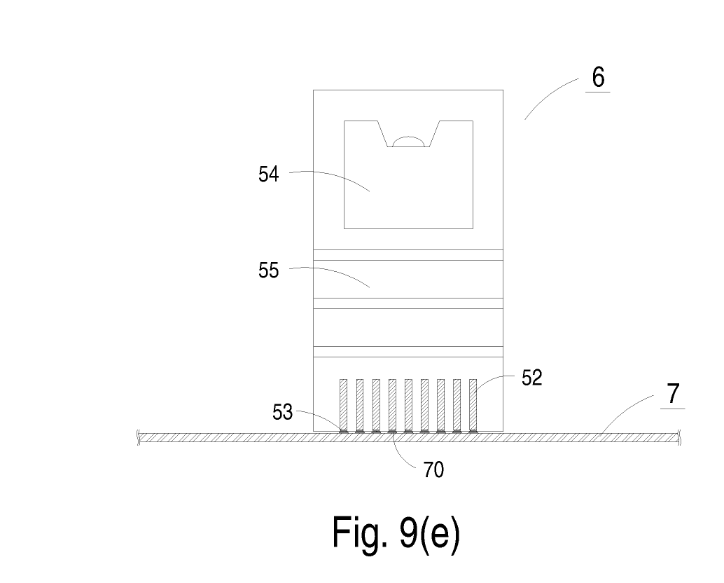

A further embodiment of the process of manufacturing the circuit module of the present invention and electrically connecting the circuit module with a system circuit board will be illustrated with reference to FIGS. 9(a)˜9(e).

First of all, as shown in FIG. 9(a), a substrate 51 is provided. The substrate 51 is made of epoxy resin or other plastic material according to known process of fabricating printed wire boards. Then, a thin conductive layer such as a copper foil layer is formed on one or both surfaces of the substrate 51. After the undesired conductive layer is removed, the designed trace pattern 52 is printed on the substrate 51 thereby fabricating a printed wire board (PWB) 5. Then, a portion of the printed wire board 5 is cut off such that the terminals of the trace pattern 52 are substantially flat with respect to the edge side of the printed wire board 5.

Next, as shown in FIG. 9(b), the terminals of the trace pattern 52 are etched to form indentations 510. As is also shown in FIG. 9(e), the locations of the indentations 510 correspond to those of first contact portions 70 (e.g. contact pads) on a system circuit board 7. Then, metallization are implemented on the sidewalls of the indentations 510 by an electroplating technology, thereby forming second contact portions 53 of the printed wire board 5, as can be seen in FIG. 9(c). In this embodiment, the surfaces of the second contact portions 53 are substantially flat with respect to the edge side of the printed wire board 5. Alternatively, there is a gap (not shown) between the second contact portions 53 and the edge side of the printed wire board 5.

Next, as shown in FIG. 9(d), an electronic component 54 and/or a heat sink 55 are mounted on the printed wire board 5 by for example a surface mount technology (SMT), thereby fabricating the power module 6. In this embodiment, the electronic component 54 indicates at least a capacitor, at least a resistor, at least an inductor, at least a transformer, at least a diode, at least a transistor and the like. For clarification, only one electronic component is shown in the drawings. An example of the transformer includes the conventional transformer, plate-to-plate sandwiched transformer, and the like.

Afterwards, as shown in FIG. 9(e), a solder paste is coated onto the first contact portions 70 of the system circuit board 7, and then the second contact portions 53 of the power module 6 are precisely placed on the first contact portions 70. By using a surface mount technology (SMT), the second contact portions 53 are welded onto the first contact portions 70, so that the power module 6 is mounted on the system circuit board 7.

It is noted that the support pins 27, conductive elements 28 and the support structure 29 used in the first embodiment are useful for assisting the power module 6 to be firmly fixed on the system circuit board 7.

As previously described, the convention edge connectors 13, 14 and 15 are disadvantageous because they have huge overall volume and increased power loss. According to the present invention, since the edge contact portions of the circuit module are directly welded on corresponding contact pads on the system circuit board, the edge connector is dispensed with. Therefore, the circuit module of the present invention is cost-effective and has low power loss. Moreover, by the known PTH technology, the edge contact portions of the circuit module are produced without difficulty.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A circuit module to be mounted on a system circuit board having first contact portions, said circuit module comprising:
a printed wire board including a substrate and a trace pattern formed on at least a surface of said substrate, wherein at least an edge side of said substrate has second contact portions corresponding to said first contact portions of said system circuit board and in contact with said trace pattern; and
at least an electronic component mounted on said printed wire board.

2. The circuit module according to claim 1 further comprising a heat sink mounted on said printed wire board.

3. The circuit module according to claim 1 wherein said circuit module is a power module.

4. The circuit module according to claim 1 wherein said second contact portions are substantially flat with respect to said edge side of said printed wire board.

5. The circuit module according to claim 1 wherein there is a gap between said second contact portions and said edge side of said printed wire board.

6. The circuit module according to claim 1 wherein at least a support pin is mounted on said printed wire board for assisting said printed wire board to be firmly fixed on said system circuit board.

7. A process of manufacturing a circuit module to be mounted on a system circuit board, said system circuit board having first contact portions, said process comprising steps of:
providing a substrate and forming a trace pattern on said substrate, thereby producing a printed wire board;
forming second contact portions on at least an edge side of said printed wire board corresponding to said first contact portions of said system circuit board and said trace pattern of said printed wire board; and
mounting electronic components on said printed wire board according to said trace pattern.

8. The process according to claim 7 wherein said first contact portions are contact pads.

9. The process according to claim 7 wherein the step of forming said trace pattern on said substrate comprises sub-steps of:
forming a conductive layer on at least a surface of said substrate; and
removing undesired portion of said conductive layer to define said trace pattern on said substrate.

10. The process according to claim 7 wherein the step of forming said second contact portions on said at least an edge side of said printed wire board comprises sub-steps of:
forming a plurality of plated through-holes in said printed wire board corresponding to said first contact portions of said system circuit board and said trace pattern of said printed wire board; and
cutting said printed wire board along said plated through-holes, thereby forming said second contact portions on said at least an edge side of said printed wire board.

11. The process according to claim 10 wherein the step of forming said plated through-holes comprises sub-steps of:
drilling a plurality of through holes in said printed wire board; and
implementing metallization on the sidewalls of said through holes by an electroplating technology, thereby forming said plated through-holes.

12. The process according to claim 11 wherein said second contact portions are substantially flat with respect to said edge side of said printed wire board after the step of cutting said printed wire board along said plated through-holes is implemented.

13. The process according to claim 11 wherein there is a gap between said second contact portions and said edge side of said printed wire board after the step of cutting said printed wire board along said plated through-holes is implemented.

14. The process according to claim 10 wherein said second contact portions and at least a support structure are simultaneously formed during the step of cutting said printed wire board along said plated through-holes.

15. The process according to claim 7 wherein said electronic components are mounted on said printed wire board by a surface mount technology (SMT).

16. The process according to claim 15 wherein at least a support pin is mounted on said printed wire board during said electronic components are mounted on said printed wire board.

17. The process according to claim 7 further comprising a step of forming a plurality of conductive elements enclosing and contacting said second contact portions.

18. The process according to claim 7 wherein the step of forming said second contact portions on said at least an edge side of said printed wire board comprises sub-steps of:
forming a plurality of indentations on at least an edge side of said printed wire board corresponding to said first contact portions of said system circuit board and said trace pattern of said printed wire board; and
implementing metallization on the sidewalls of said indentations by an electroplating technology, thereby forming said second contact portions on said at least an edge side of said printed wire board.

19. A process of manufacturing a circuit module to be mounted on a system circuit board, said system circuit board having first contact portions, said process comprising steps of:
providing a substrate and forming a trace pattern on said substrate, thereby producing a printed wire board;
forming second contact portions on at least an edge side of said printed wire board corresponding to said first contact portions of said system circuit board and said trace pattern of said printed wire board;
mounting electronic components on said printed wire board according to said trace pattern; and
welding said second contact portions of said printed wire board onto said first contact portions of said system circuit board.

20. The process according to claim 19 wherein said printed wire board has at least a first retaining hole corresponding to at least a second retaining hole in said system circuit board, wherein first and second ends of at least a support pin are welded in said first and second retaining holes, respectively.
